(19) United States
(12) Patent Application Publication
(10) Pub. No.: US 2026/0244161 A1
(43) Pub. Date: Aug. 20, 2026

(54) VOLTAGE DETECTION CIRCUIT AND WATCH

(71) Applicant: CITIZEN WATCH CO., LTD., Nishitokyo-Shi, Tokyo (JP)

(72) Inventor: Masahiko HITOMI, Nishitokyo-shi, Tokyo (JP)

(73) Assignee: CITIZEN WATCH CO., LTD., Nishitokyo-Shi, Tokyo (JP)

(21) Appl. No.: 19/158,939

(22) PCT Filed: Jan. 22, 2024
(86) PCT No.: PCT/JP2024/001690

§ 371 Date: Aug. 22, 2025

(30) Foreign Application Priority Data
Mar. 16, 2023 (JP) 2023-042279

(51) Int. Cl. G04C 10/04; G01R 19/165; G04G 19/02

(52) U.S. Cl. CPC G04C 10/04; G01R 19/16509; G01R 19/16542; G04G 19/02

(57) ABSTRACT

A voltage detection circuit includes: a comparator having a first input terminal to which a reference voltage is input, and a second input terminal; a plurality of fine adjustment resistors arranged between a detection target and the second input terminal; at least one coarse adjustment resistor disposed between the detection target and the second input terminal; a fine adjustment switch unit that connects an arbitrary number of the fine adjustment resistors to the detection target and the coarse adjustment resistor in series; a coarse adjustment switch unit that connects an arbitrary number of the coarse adjustment resistors to the detection target and the fine adjustment resistors in series; and a control unit. The control unit controls an opening and closing operation of a switch included in the fine adjustment switch unit and the coarse adjustment switch unit.

### FIELD

The present invention relates to a voltage detection circuit and a watch.

### BACKGROUND

In the related art, there are voltage detection circuits. Patent Literature 1 discloses a voltage detection circuit including: a resistance voltage dividing circuit having a rough adjustment variable resistance circuit and a fine adjustment variable resistance circuit; a rough adjustment unit that controls the rough adjustment variable resistance circuit; a fine adjustment unit that controls the fine adjustment variable resistance circuit; and a control unit that controls the rough adjustment unit and the fine adjustment unit in response to a detection signal of a comparison circuit.

### CITATION LIST

### Patent Literature

Patent Literature 1: Japanese Patent Application Laid-open No. JP 2020-016578 A

### SUMMARY

### Technical Problem

In a voltage detection circuit, it is desirable to improve the detection resolution without increasing the circuit scale. For example, it is preferable to improve the detection resolution while suppressing the number of resistors.

An object of the present invention is to provide a voltage detection circuit and a watch that solve the above-described issues.

### Solution to Problem

The present invention is characterized in that a voltage detection circuit includes a comparator having a first input terminal to which a reference voltage is input, and a second input terminal; a plurality of fine adjustment resistors arranged between a detection target and the second input terminal; at least one coarse adjustment resistor disposed between the detection target and the second input terminal; a fine adjustment switch unit that connects an arbitrary number of the fine adjustment resistors to the detection target and the coarse adjustment resistor in series; a coarse adjustment switch unit that connects an arbitrary number of the coarse adjustment resistors to the detection target and the fine adjustment resistors in series; and a control unit that controls an opening and closing operation of a switch included in the fine adjustment switch unit and an opening and closing operation of a switch included in the coarse adjustment switch unit, wherein the coarse adjustment resistor includes a resistor having a resistance value equal to a total value obtained by adding up resistance values of the plurality of fine adjustment resistors.

### Advantageous Effects of Invention

A voltage detection circuit according to the present invention includes: a plurality of fine adjustment resistors; a coarse adjustment resistor disposed between a detection target and a second input terminal of a comparator; a fine adjustment switch unit that connects an arbitrary number of fine adjustment resistors to the detection target and the coarse adjustment resistor in series; and a coarse adjustment switch unit that connects an arbitrary number of coarse adjustment resistors to the detection target and the fine adjustment resistors in series. The coarse adjustment resistor includes a resistor having a resistance value equal to a total value obtained by adding up resistance values of the plurality of fine adjustment resistors. According to the voltage detection circuit of the present invention, the combination of the fine adjustment resistors and the coarse adjustment resistor can achieve the effect of improving the detection resolution.

### BRIEF DESCRIPTION OF DRAWINGS

FIG. 1 is a diagram illustrating a watch according to an embodiment.

FIG. 2 is a diagram illustrating a voltage detection circuit according to the embodiment.

FIG. 3 is a flowchart illustrating an operation of the voltage detection circuit according to the embodiment.

FIG. 4 is a diagram of a detection sequence according to the embodiment.

FIG. 5 is a diagram of a detection sequence according to the embodiment.

FIG. 6 is a graph of detection characteristics of a comparator.

FIG. 7 is a diagram of a voltage detection circuit according to a first modification of the embodiment.

FIG. 8 is a diagram of a voltage detection circuit according to a second modification of the embodiment.

### DESCRIPTION OF EMBODIMENTS

Hereinafter, a voltage detection circuit according to an embodiment of the present invention will be described in detail with reference to the drawings. Note that the present invention is not limited by the embodiment. In addition, components in the following embodiment include those that can be easily conceived of by those skilled in the art and those that are substantially the same.

### EMBODIMENTS

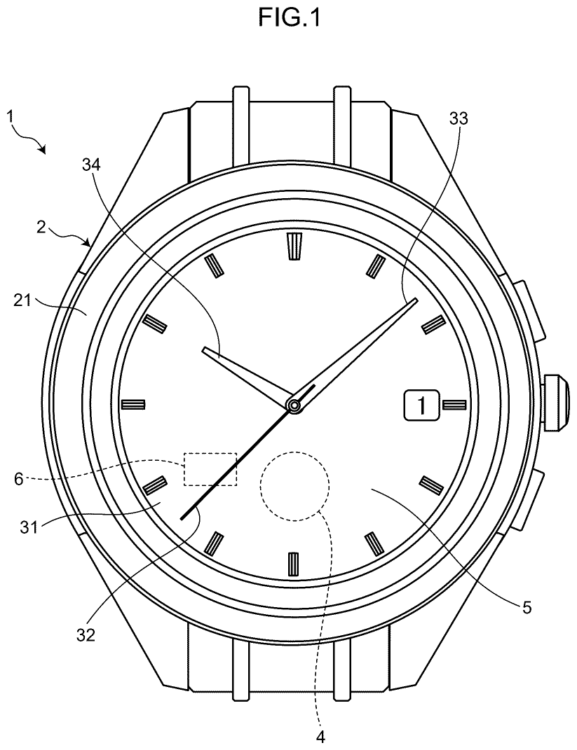

An embodiment will be described with reference to FIGS. 1 to 6. The present embodiment relates to a voltage detection circuit. As illustrated in FIG. 1, a watch 1 according to the embodiment includes an exterior case 2, a battery 4, a windshield 5, a voltage detection circuit 6, a dial plate 31, a second hand 32, a minute hand 33, and an hour hand 34. The watch 1 of the present embodiment is an electronic watch and calculates an internal time on the basis of a clock signal generated by an oscillation circuit.

The exterior case 2 includes a case body 21 having a substantially cylindrical shape. The battery 4, the voltage detection circuit 6, the dial plate 31, the second hand 32, the minute hand 33, and the hour hand 34 are housed in the case body 21. The windshield 5 is a transparent member that closes an opening on the front side of the exterior case 2. The opening on the back side of the exterior case 2 is closed by a back lid.

The battery 4 is a chargeable and dischargeable secondary battery. The watch 1 calculates the internal time by electric power supplied from the battery 4 and moves the second hand 32, the minute hand 33, and the hour hand 34. The watch 1 may have a power generation unit such as a solar cell. In this case, the electric power generated by the power generation unit is stored in the battery 4.

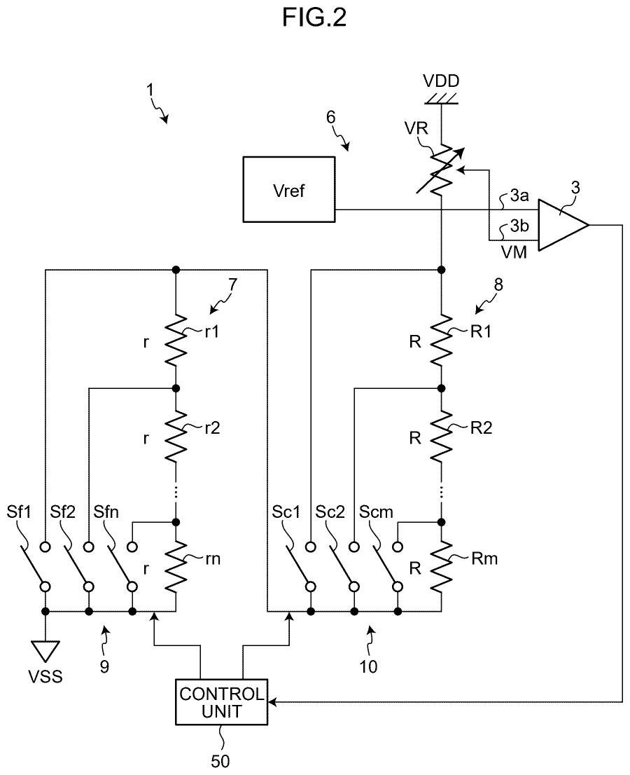

The voltage detection circuit 6 is a circuit that detects the voltage of the battery 4 as a power supply VSS. As illustrated in FIG. 2, the voltage detection circuit 6 includes a comparator 3, a first resistor group 7 for fine adjustment, a second resistor group 8 for coarse adjustment, a fine adjustment switch unit 9, a coarse adjustment switch unit 10, a variable resistor VR, and a control unit 50.

The comparator 3 is a comparing device and has a first input terminal 3a and a second input terminal 3b. A predetermined reference voltage Vref is input to the first input terminal 3a. The reference voltage Vref may be generated from the output voltage of the power supply VSS. An input voltage VM is input to the second input terminal 3b. The input voltage VM is a voltage obtained by dividing the voltage of the power supply VSS by the first resistor group 7, the second resistor group 8, and the variable resistor VR. An electrical potential of the power supply VSS with respect to the ground potential VDD has, for example, a negative value.

The comparator 3 outputs a signal corresponding to a comparison result between the reference voltage Vref and the input voltage VM. The comparator 3 of the present embodiment outputs a detection signal in a case where the electrical potential of the input voltage VM is lower than the electrical potential of the reference voltage Vref. The detection signal is, for example, a high-level ON signal. On the other hand, the comparator 3 outputs a non-detection signal in a case where the electrical potential of the input voltage VM is higher than the electrical potential of the reference voltage Vref. The non-detection signal is, for example, a low-level off signal.

The first resistor group 7, the second resistor group 8, and the variable resistor VR are arranged in series from the power supply VSS side to the ground potential VDD side in this order. The variable resistor VR may be a switching-type resistor device having a plurality of resistors or may be a potentiometer. The variable resistor VR changes the resistance value between the second input terminal 3b and the ground potential VDD. The variable resistor VR is controlled by the control unit 50, for example.

The first resistor group 7 and the second resistor group 8 are arranged between the power supply VSS and the second input terminal 3b. The second resistor group 8 is a resistor that roughly adjusts the total resistance value between the power supply VSS and the second input terminal 3b. The first resistor group 7 is a resistor that finely adjusts the total resistance value between the power supply VSS and the second input terminal 3b

The first resistor group 7 has a plurality of fine adjustment resistors ri (i=1, 2, . . . , n). The plurality of fine adjustment resistors ri have the same resistance value r [Ω]. The plurality of fine adjustment resistors ri are connected continuously and in series. The fine adjustment resistors r1, r2, . . . , and rn are arranged in this order mentioned from the second resistor group 8 toward the power supply VSS.

The fine adjustment switch unit 9 connects an arbitrary number of fine adjustment resistors ri to the power supply VSS and the second resistor group 8 in series. The fine adjustment switch unit 9 includes a plurality of switches Sfi (i=1, 2, . . . , n). The switches Sfi are, for example, NMOS transistors. Closing the switch Sf1 results in bypassing all the fine adjustment resistors ri. That is, the switch Sfi can short-circuit both ends of the first resistor group 7. Closing the switch Sf2 results in bypassing from the fine adjustment resistor r2 to the fine adjustment resistor rn. That is, closing an i-th switch Sfi results in bypassing from the fine adjustment resistor ri to the fine adjustment resistor rn. Closing the switch Sfn results in bypassing the fine adjustment resistor rn.

In the following description, among the plurality of fine adjustment resistors ri, a resistor that is not bypassed by a switch Sfi is referred to as an “effective resistor”. The resistance value rs of the first resistor group 7 is a sum of the resistance values of effective fine adjustment resistors ri.

The fine adjustment switch unit 9 can interpose an arbitrary number of fine adjustment resistors ri from 0 to n as effective resistors between the power supply VSS and the second resistor group 8. In a case where the number of fine adjustment resistors ri to be enabled is one, the switch Sf1 is opened and all the switches from the switch Sf2 to Sin are closed. That is, the fine adjustment resistor r1 is connected in series to the power supply VSS and the second resistor group 8. As a result, the resistance value rs of the first resistor group 7 is given by r [Ω].

In a case where p (2<p<n) fine adjustment resistors ri are enabled, the switch Sf1 to the switch Sfp are opened, and all the other switches Sfi are closed. That is, the fine adjustment resistors r1, r2, . . . , rp are connected in series to the power supply VSS and the second resistor group 8. As a result, the resistance value rs of the first resistor group 7 is given by p×r [Ω]. In a case where all the fine adjustment resistors ri are enabled, all the switches Sfi are opened. As a result, the resistance value rs of the first resistor group 7 is given by n×r [Ω].

The second resistor group 8 includes at least one coarse adjustment resistor Rj (j=1, 2, . . . , m). Each of the coarse adjustment resistors Rj of the present embodiment has the same resistance value R [Ω]. In a case where the second resistor group 8 has a plurality of coarse adjustment resistors Rj, the plurality of coarse adjustment resistors Rj are connected continuously and in series. The plurality of coarse adjustment resistors R1, R2, . . . , and Rj are arranged in this order from the first resistor group 7 to the ground potential VDD. The resistance value R [Ω] of one coarse adjustment resistor Rj is equal to a sum of the resistance values r [Ω] of the plurality of fine adjustment resistors ri. That is, the following Equation (1) holds.

$$R = n \times r \qquad ( 1 )$$

The coarse adjustment switch unit 10 connects an arbitrary number of coarse adjustment resistors Rj to the power supply VSS and the first resistor group 7 in series. The coarse adjustment switch unit 10 includes a plurality of switches Scj (j=1, 2, . . . , m). The switches Scj are, for example, NMOS transistors. Closing the switch Sc1 results in bypassing all the coarse adjustment resistors Rj. That is, the switch Sc1 can short-circuit both ends of the second resistor group 8. Closing the switch Sc2 results in bypassing from the coarse adjustment resistor R2 to the coarse adjustment resistor Rm. That is, closing the j-th switch Scj results in bypassing from the coarse adjustment resistor Rj to the coarse adjustment resistor Rm. Closing the switch Scm results in bypassing the coarse adjustment resistor Rm.

In the following description, among the plurality of coarse adjustment resistors Rj, a resistor that is not bypassed by a switch Scj is referred to as an “effective resistor”. The resistance value Rs of the second resistor group 8 is a sum of the resistance values of effective coarse adjustment resistors Rj.

The coarse adjustment switch unit 10 can interpose an arbitrary number of coarse adjustment resistors Rj from zero to m as effective resistors between the first resistor group 7 and the ground potential VDD. In a case where the number of coarse adjustment resistors Rj to be enabled is one, the switch Sc1 is opened, and all of the switches Sc2 to the switches Scm are closed. That is, the coarse adjustment resistor R1 is connected in series to the power supply VSS and the first resistor group 7. As a result, the resistance value Rs of the second resistor group 8 is given by R [Ω].

In a case where q (2<q<m) coarse adjustment resistors Rj are enabled, the switch Sc1 to the switch Scq are opened, and all the other switches Scj are closed. That is, the coarse adjustment resistors R1, R2, . . . , Rq are connected in series to the power supply VSS and the first resistor group 7. As a result, the resistance value Rs of the second resistor group 8 is given by q×R [Ω]. In a case where all the coarse adjustment resistors Rj are enabled, all the switches Scj are opened. As a result, the resistance value Rs of the second resistor group 8 is given by m×R [Ω].

The control unit 50 controls the operation of the voltage detection circuit 6. The control unit 50 is, for example, a control circuit configured to perform a predetermined operation. The control unit 50 controls the fine adjustment switch unit 9, the coarse adjustment switch unit 10, and the variable resistor VR. More specifically, the control unit 50 controls the opening and closing operation of each of the switches Sfi included in the fine adjustment switch unit 9. The control unit 50 can control the open or closed state of each of the switches Sfi independently of the open or closed state of the other switches Sfi. In addition, the control unit 50 controls the opening and closing operation of each of the switches Scj included in the coarse adjustment switch unit 10. The control unit 50 can control the open or closed state of each of the switches Scj independently of the open or closed state of the other switches Scj. In addition, the control unit 50 acquires an output signal of the comparator 3. The control unit 50 executes a voltage detection operation in response to a command from a watch control unit or the like.

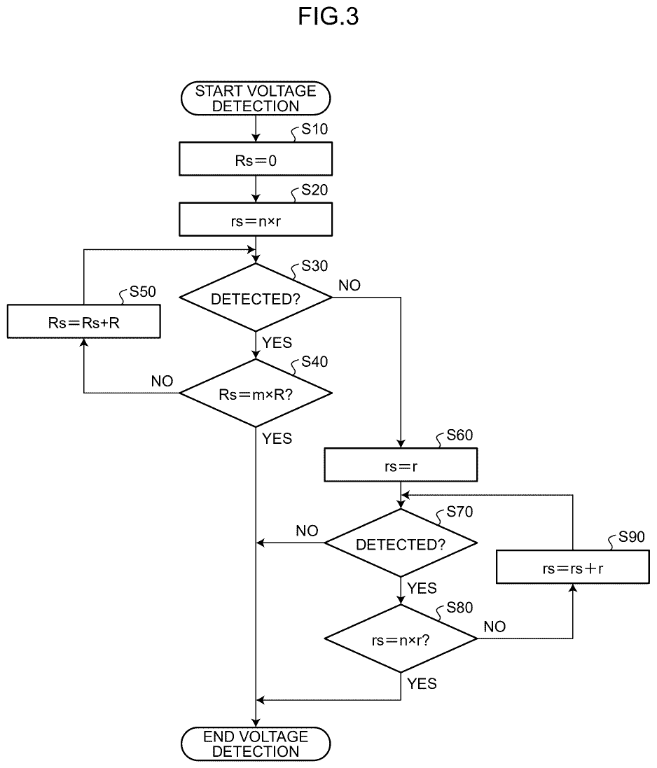

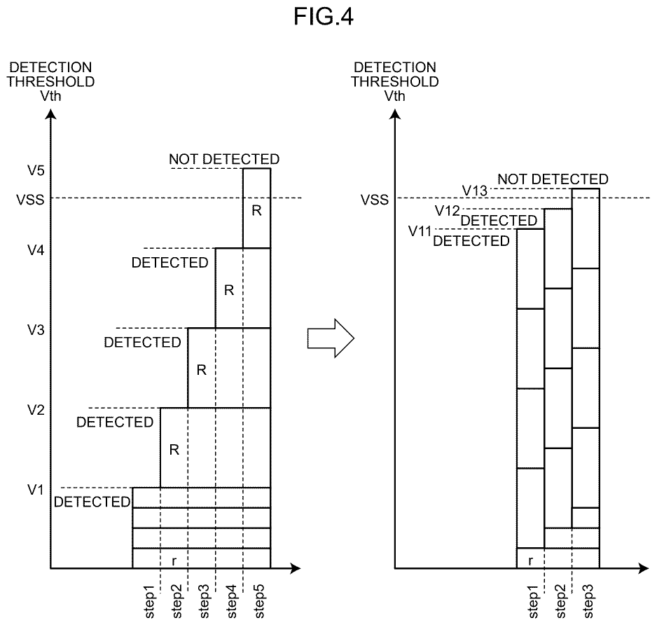

Illustrated in FIG. 3 is a flowchart of a voltage detection operation by the control unit 50 of the present embodiment. Illustrated in FIG. 4 is an example of the voltage detection operation according to the flowchart of FIG. 3. In FIG. 4, the left side is a coarse adjustment detection sequence and corresponds to Steps S10 to S50 of the flowchart. The right side of FIG. 4 is a fine adjustment detection sequence and corresponds to Steps S60 to S90 of the flowchart. In the following description, the coarse adjustment detection sequence is referred to as a “first sequence”, and the fine adjustment detection sequence is referred to as a “second sequence”.

As illustrated in FIG. 4, in the first sequence, the total resistance value is incremented by R [Ω] until the signal of the comparator 3 changes from detection to non-detection. The total resistance value is a total value of the resistance value rs of the first resistor group 7 and the resistance value Rs of the second resistor group 8. That is, the total resistance value is a resistance value between the power supply VSS and the second input terminal 3b

In Step S10 of FIG. 3, the control unit 50 sets the resistance value Rs of the second resistor group 8 to 0 [Ω]. The control unit 50 closes all the switches Scj of the coarse adjustment switch unit 10. When Step S10 is executed, the process proceeds to Step S20.

In Step S20, the control unit 50 sets the resistance value rs of the first resistor group 7 to n×r [Ω], which is the maximum value. Step S20 corresponds to the first increment in the resistance value in the first sequence of the coarse adjustment in FIG. 4 (step 1). The control unit 50 opens all the switches Sfi of the fine adjustment switch unit 9. As a result, the fine adjustment resistors r1, r2, . . . , and rn connected in series with each other are interposed as effective resistors between the power supply VSS and the second input terminal 3b. Therefore, the total resistance value is R [Ω]. When Step S20 is executed, the process proceeds to Step S30.

In Step S30, the control unit 50 determines whether or not a detection signal is acquired from the comparator 3. As a result of the determination in Step S30, if positive determination is made that a detection signal is acquired, the process proceeds to Step S40, and if negative determination is made, the process proceeds to Step S60.

In Step S40, the control unit 50 determines whether or not the resistance value Rs of the second resistor group 8 is m×R [Ω], which is the maximum value. If positive determination is made as a result of the determination in Step S40, the voltage detection ends, and if negative determination is made, the process proceeds to Step S50. If positive determination is made in Step S40, since the total value of the resistance value rs of the first resistor group 7 and the resistance value Rs of the second resistor group 8 has reached the maximum value, the control unit 50 determines that the voltage of the power supply VSS is larger than an upper limit threshold Vth that is detectable and ends the voltage detection.

In Step S50 of FIG. 3, the control unit 50 increases the resistance value Rs of the second resistor group 8 by R [Ω]. That is, in the second resistor group 8, the number of coarse adjustment resistors Rj enabled between the first resistor group 7 and the second input terminal 3b is increased by one. The control unit 50 opens one switch Scj corresponding to a coarse adjustment resistor Rj to be enabled in the coarse adjustment switch unit 10.

Step S50 corresponds to second and subsequent increases in the resistance value (steps 2 to 5) in the first sequence of FIG. 4. When Step S50 is executed, the process shifts to Step S30. In the coarse adjustment on the left side of FIG. 4, the output of the comparator 3 is the detection signal while the total resistance value is less than or equal to 4×R [Ω], and the signal changes to a non-detection signal when the total resistance value reaches 5×R [Ω]. In other words, the output of the comparator 3 is switched to the non-detection signal by a fifth increase in the resistance value (step 5). As a result, negative determination is made in Step S30, the process proceeds to Step S60, and the second sequence of fine adjustment is started.

In Step S60, the control unit 50 sets the resistance value rs of the first resistor group 7 to r [Ω]. The control unit 50 opens the switch Sf1 of the fine adjustment switch unit 9 and closes the other switches Sf2, . . . , and Sfn. Step S60 corresponds to a first resistance value change (step 1) in the second sequence illustrated on the right side of FIG. 4. When Step S60 is executed, the process proceeds to Step S70.

In Step S70, the control unit 50 determines whether or not a detection signal is acquired from the comparator 3. As a result of the determination in Step S70, if positive determination is made that a detection signal is acquired, the process proceeds to Step S80, and if negative determination is made, the voltage detection ends.

If negative determination is made in Step S70, the control unit 50 determines that the voltage of the power supply VSS is smaller than the threshold Vth. In addition, the control unit 50 can calculate the voltage value of the power supply VSS on the basis of the total resistance value. In FIG. 4, in the second sequence, the output of the comparator 3 is switched to the non-detection signal at a third resistance value change (step 3). In this case, the voltage value of the power supply VSS is calculated on the basis of the total resistance value immediately before (step 2).

In Step S80, the control unit 50 determines whether or not the resistance value rs of the first resistor group 7 is n×r [Ω], which is the maximum value. If positive determination is made as a result of the determination in Step S80, the voltage detection ends, and if negative determination is made, the process proceeds to Step S90. If the resistance value rs of the first resistor group 7 is the maximum value and positive determination is made in Step S80, the flowchart of FIG. 3 may be executed again. In this case, the process proceeds to Step S10, and the procedure of voltage detection is executed from the beginning.

In Step S90, the control unit 50 increases the resistance value rs of the first resistor group 7 by r [Ω]. That is, in the first resistor group 7, the number of fine adjustment resistors ri interposed as an effective resistor between the power supply VSS and the second resistor group 8 is increased by one. The control unit 50 opens one switch Sfj corresponding to the fine adjustment resistor ri to be enabled in the fine adjustment switch unit 9. When Step S90 is executed, the process shifts to Step S70.

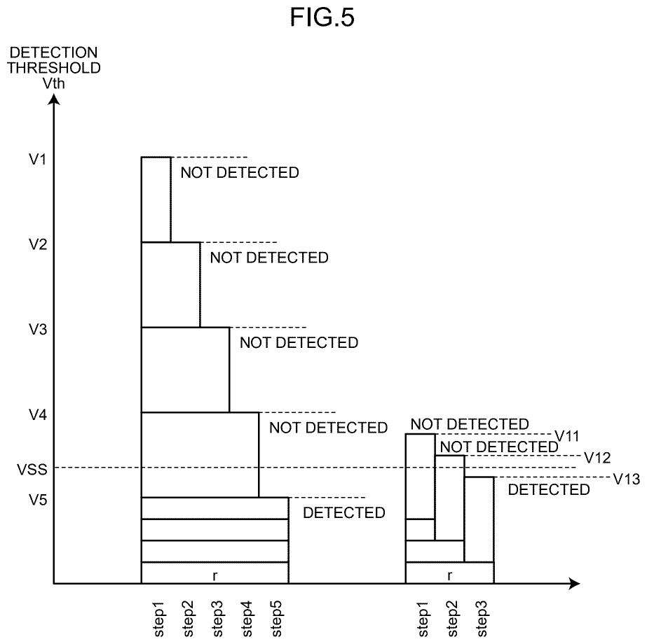

Contrary to the flowchart of FIG. 3, the voltage detection may be performed while the total resistance value is decreased. Illustrated in FIG. 5 is a first sequence and a second sequence in a case where voltage detection is performed while the total resistance value is reduced. In this case, each of the detection sequences is terminated with the output of the comparator 3 switched from a non-detection signal to a detection signal.

In the first sequence of the coarse adjustment illustrated on the left side of FIG. 5, first, the total resistance value is regarded as the maximum value (step 1). Then, the number of effective coarse adjustment resistors Rj is decreased one by one in the second resistor group 8 (from step 2 to step 5). In the example of FIG. 5, the output of the comparator 3 is switched to a detection signal in step 5, the first sequence ends, and the process proceeds to the second sequence.

In the second sequence of fine adjustment on the right side of FIG. 5, first, the number of effective coarse adjustment resistors Rj in the second resistor group 8 is increased by one (step 1). Then, the number of effective fine adjustment resistors ri is decreased one by one (from step 2 to step 3). In the example of FIG. 5, the output of the comparator 3 is switched to a detection signal in step 3, and the voltage detection ends.

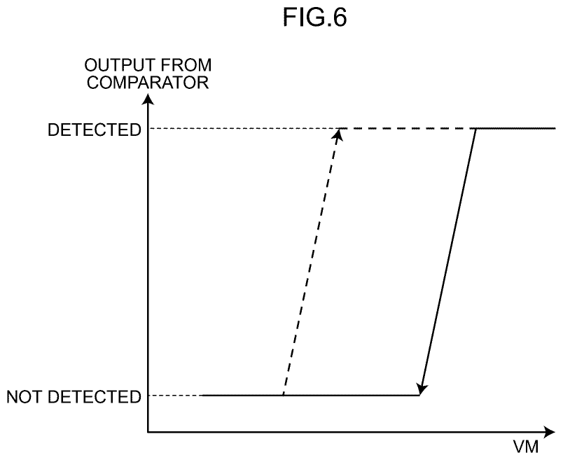

As described above, in a case where voltage detection is performed while the total resistance value is reduced, the resistance value is reduced in both the coarse adjustment and the fine adjustment. That is, in the coarse adjustment and the fine adjustment, the increasing or decreasing direction of the total resistance value is the same. This suppresses a decrease in the detection accuracy due to hysteresis. Illustrated in FIG. 6 is detection characteristics of the comparator. As illustrated in FIG. 6, there is hysteresis in the voltage value in the case of switching from non-detection to detection and the case of switching from detection to non-detection. The voltage detection method of the present embodiment can avoid the influence of the hysteresis.

As described above, the voltage detection circuit 6 of the present embodiment includes the comparator 3, the plurality of fine adjustment resistors ri, at least one coarse adjustment resistor Rj, the fine adjustment switch unit 9, and the coarse adjustment switch unit 10. The comparator 3 has the first input terminal 3a to which the reference voltage Vref is input and the second input terminal 3b. The plurality of fine adjustment resistors ri are arranged between a detection target and the second input terminal 3b. The coarse adjustment resistor Rj is disposed between the detection target and the second input terminal 3b.

The fine adjustment switch unit 9 connects an arbitrary number of fine adjustment resistors ri to the detection target and the coarse adjustment resistor Rj in series. The coarse adjustment switch unit 10 connects an arbitrary number of coarse adjustment resistors Rj to the detection target and the fine adjustment resistors ri in series. The coarse adjustment resistors Rj include a resistor having a resistance value equal to the total value of the resistance values of the plurality of fine adjustment resistors ri. In the present embodiment, the resistance value R [Ω] of all the coarse adjustment resistors Rj is equal to the total value n×r [Ω]. The voltage detection circuit 6 of the present embodiment can improve versatility by improving voltage detection resolution.

The voltage detection circuit 6 of the present embodiment includes a variable resistor VR that changes the resistance value between the second input terminal 3b of the comparator 3 and the ground potential VDD. A voltage divided by the variable resistor VR, the fine adjustment resistors ri, and the coarse adjustment resistors Rj is input to the second input terminal 3b of the comparator 3. The variable resistor VR can change the range of voltage detection and change the resolution of voltage detection.

The control unit 50 of the present embodiment executes a first sequence that is a coarse adjustment detection sequence and a second sequence that is a fine adjustment detection sequence. The first sequence is a sequence in which the number of coarse adjustment resistors Rj connected in series to the power supply VSS as the detection target and the fine adjustment resistors ri is changed until the output of the comparator 3 is switched. The second sequence is a sequence in which the number of fine adjustment resistors ri connected in series to the power supply VSS as the detection target and the coarse adjustment resistors Rj is changed in a range of resistance values before and after the output of the comparator 3 is switched in the first sequence.

For example, in the first sequence illustrated on the left side of FIG. 4, when the total resistance value increases from 4×R [Ω] to 5×R [Ω], the output of the comparator 3 switches from detection to non-detection. In this case, in the second sequence on the right side, the control unit 50 changes the number of effective fine adjustment resistors ri in the range of resistance values between 4×R [Ω] before the output change and 5×R [Ω] after the output change.

In the case of increasing the number of coarse adjustment resistors Rj connected in series in the first sequence, the control unit 50 increases the number of fine adjustment resistors ri connected in series in the second sequence. On the other hand, in the case of decreasing the number of coarse adjustment resistors Rj connected in series in the first sequence, the control unit 50 decreases the number of fine adjustment resistors ri connected in series in the second sequence. As a result, the influence of the hysteresis of the comparator 3 is avoided, and the detection accuracy is improved.

In the voltage detection circuit 6 of the present embodiment, the first resistor group 7 is disposed closer to the power supply VSS as the detection target than the second resistor group 8 is. Also, the fine adjustment switch unit 9 is disposed on the side of the power supply VSS as the detection target with respect to the coarse adjustment resistors Rj. As a result, the influence of the resistance of the switches Sfi on the voltage detection of the power supply VSS is reduced. Therefore, the voltage detection circuit 6 of the present embodiment can improve the voltage detection accuracy.

The voltage detection circuit 6 of the present embodiment enables the fine adjustment resistors ri and performs coarse detection in the first sequence of coarse adjustment. The fine adjustment resistors ri are commonly used in both the fine adjustment and coarse adjustment detection sequences, whereby the detection accuracy can be improved.

The detection target of the voltage detection circuit 6 is not limited to the voltage of the power supply VSS. The voltage detection circuit 6 can be used for various types of voltage detection in the watch 1. Moreover, the application target of the voltage detection circuit 6 is not limited to watches. The voltage detection circuit 6 may be applied to portable electronic devices or may be applied to other devices.

### First Modification of Embodiment

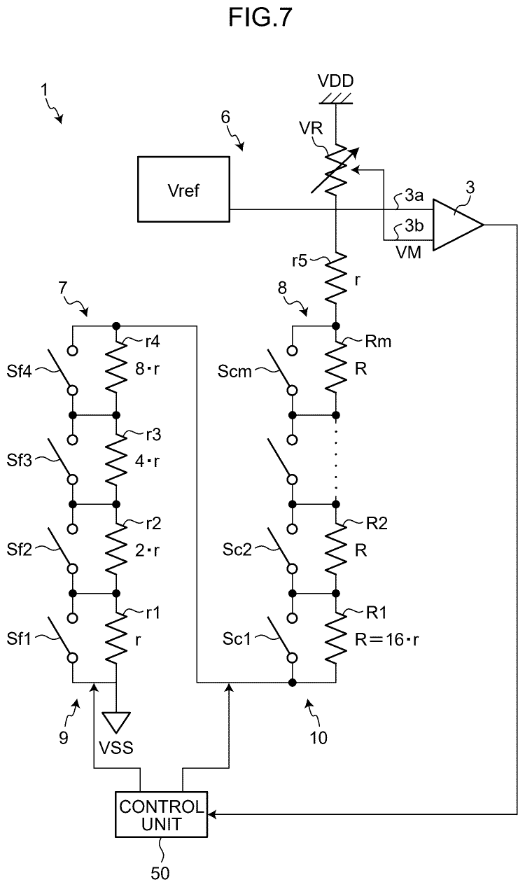

A first modification of the embodiment will be described with reference to FIG. 7. FIG. 7 is a diagram of a voltage detection circuit according to the first modification of the embodiment. The first modification of the embodiment is different from the above embodiment in that, for example, the resistance value of a first resistor group 7 is weighted.

The first resistor group 7 of the first modification has four fine adjustment resistors ri (i=1, 2, 3, and 4) having resistance values different from each other. The first resistor group 7 further includes a fine adjustment resistor r5 that is always connected to a power supply VSS. The fine adjustment resistor r5 is always effective. The four fine adjustment resistors r1, r2, r3, and r4 are arranged between the power supply VSS and a second resistor group 8 and are connected to each other in series. The fine adjustment resistors r1, r2, r3, and r4 are arranged in this order from the power supply VSS side toward the second resistor group 8.

The four fine adjustment resistors ri (i=1, 2, 3, and 4) have a resistance value rf (i). The minimum value of the resistance value rf (i) of the four fine adjustment resistors ri (i=1, 2, 3, and 4) is r [Ω]. In FIG. 7, the fine adjustment resistor r1 has the minimum resistance value r [Ω]. The resistance value rf (i) of the fine adjustment resistor ri (i=1, 2, 3, 4) is defined as the following Equation (2).

$$rf ( i ) = {2}^{i - 1} \times r \qquad ( 2 )$$

That is, the resistance value rf (2) of the fine adjustment resistor r2 is 2×r [Ω], the resistance value rf (3) of the fine adjustment resistor r3 is 4×r [Ω], and the resistance value rf (4) of the fine adjustment resistor r4 is 8×r [Ω]. Note that the resistance value rf (5) of the fine adjustment resistor r5 is r [Ω].

The fine adjustment switch unit 9 connects an arbitrary number of fine adjustment resistors ri to the power supply VSS and the second resistor group 8 in series. The fine adjustment switch unit 9 of the first modification includes a plurality of switches Sfi (i=1, 2, 3, and 4). Closing a switch Sfi results in bypassing a corresponding fine adjustment resistor ri. For example, the switch Sf1 bypasses the fine adjustment resistor r1.

The fine adjustment switch unit 9 connects one fine adjustment resistor r5 to the power supply VSS and the second resistor group 8 in series as an effective resistor in a case where all the switches Sfi are closed. In this case, the resistance value rs of the first resistor group 7 is r [Ω]. The fine adjustment switch unit 9 can connect arbitrary zero to four resistors among the four fine adjustment resistors ri (i=1, 2, 3, and 4) to the power supply VSS and the second resistor group 8 in series as effective resistors. That is, the fine adjustment switch unit 9 can form a combined resistance from 0 [Ω] to 15×r [Ω] by combining the four fine adjustment resistors ri (i=1, 2, 3, and 4). Therefore, the fine adjustment switch unit 9 can increase or decrease the resistance value rs of the first resistor group 7 by an increment of r [Ω] from r [Ω] to 16×r [Ω].

Similarly to the second resistor group 8 of the above embodiment, the second resistor group 8 of the first modification has at least one coarse adjustment resistors Rj (j=1, 2, . . . , m) having the same resistance value R [Ω]. The resistance value R [Ω] is equal to the sum of the resistance values rf (i) of the plurality of fine adjustment resistors ri. That is, the resistance value R of one coarse adjustment resistors Rj is 16×r [Ω].

The coarse adjustment switch unit 10 connects an arbitrary number of coarse adjustment resistors Rj to the power supply VSS and the first resistor group 7 in series. The coarse adjustment switch unit 10 of the first modification includes a plurality of switches Scj (j=1, 2, . . . , . . . , m). Closing a switch Scj results in bypassing a corresponding coarse adjustment resistor Rj. For example, the switch Sc1 bypasses the coarse adjustment resistor R1. In a case where all the switches Scj are closed, all the coarse adjustment resistors Rj are bypassed. That is, the coarse adjustment switch unit 10 can connect an arbitrary number of coarse adjustment resistors Rj from zero to m to the power supply VSS and the first resistor group 7 in series as effective resistors.

The voltage detection circuit 6 of the first modification can detect the voltage of the power supply VSS by a procedure substantially similar to that of the voltage detection circuit 6 of the above embodiment. A detection procedure of the voltage detection circuit 6 of the first modification will be described with reference to the flowchart of FIG. 3.

In Step S10, the control unit 50 sets the resistance value Rs of the second resistor group 8 to 0 [Ω], and in Step S20, sets the resistance value rs of the first resistor group 7 to the maximum value. In this case, the control unit 50 sets all the fine adjustment resistors ri of the first resistor group 7 as effective resistors. Therefore, the resistance value rs of the first resistor group 7 is 16×r [Ω], which is the maximum value.

Steps S30 to S50 are similar to those in the above embodiment. The control unit 50 increases the number of effective coarse adjustment resistors Rj in the second resistor group 8 until the output of the comparator 3 becomes a non-detection signal. When the non-detection signal is received from the comparator 3, the process proceeds to the second sequence of fine adjustment. In Step S60, the control unit 50 closes all the switches Sfi of the fine adjustment switch unit 9 and sets the resistance value rs of the first resistor group 7 to r [Ω]. If positive determination is made in Step S70 that the output of the comparator 3 is a detection signal, the process proceeds to Step S80.

In Step S80, the control unit 50 determines whether or not the resistance value rs of the first resistor group 7 is 16×r [Ω], which is the maximum value. If negative determination is made in Step S80 and the process proceeds to Step S90, the control unit 50 increases the resistance value rs of the first resistor group 7 by r [Ω]. If positive determination is made in Step S80, the voltage detection ends.

The voltage detection circuit 6 of the first modification of the embodiment can change the resistance value rs of the first resistor group 7 in sixteen stages by the five fine adjustment resistors ri (i=1, 2, . . . , 5). This improves the resolution and accuracy of the voltage detection.

The number of pieces n of the fine adjustment resistors ri having different resistance values is not limited to four. The first resistor group 7 can have an arbitrary number n of fine adjustment resistors ri having resistance values different from each other.

As described above, the voltage detection circuit 6 according to the first modification includes n fine adjustment resistors ri having resistance values different from each other. The n is a natural number greater than or equal to 2. The minimum value of the resistance values of the n fine adjustment resistors ri is r [Ω]. The resistance value rf (i) of each of the n fine adjustment resistors ri is 2ⁱ⁻¹×r. The voltage detection circuit 6 of the first modification can improve the detection resolution while suppressing an increase in the number of switches Sfi for fine adjustment.

In the second sequence of fine adjustment, the number of fine adjustment resistors ri whose effectiveness can be switched may be determined depending on a required resolution. The first resistor group 7 of FIG. 7 can implement a resistance value rs of level 16. Meanwhile, in a case where the resolution may be level 8, which is half the resolution, the switch Sf1 for the fine adjustment resistor r1 may be kept off (opened). In this case, the resistance value rs is switched to level 8 by the switches Sf2, Sf3, and Sf4. As a result, the maximum number of steps to determination of the detection result is reduced, whereby the detection time is shortened.

Note that, in the first resistor group 7, the fine adjustment resistor r5 may be omitted. In this case, the resistance value of the coarse adjustment resistors Rj is given by R=15×r [Ω].

### Second Modification of Embodiment

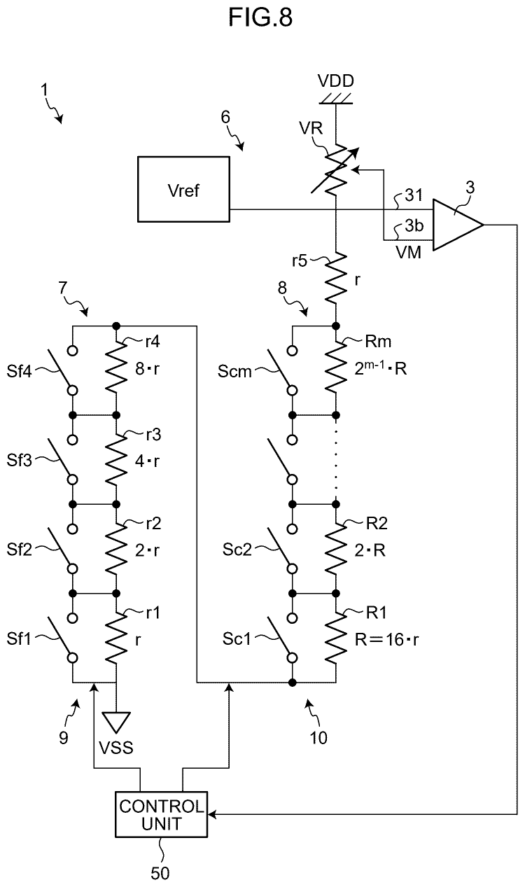

A second modification of the embodiment will be described with reference to FIG. 8. FIG. 8 is a diagram of a voltage detection circuit according to the second modification of the embodiment. The second modification of the embodiment is different from the first modification of the embodiment in that, for example, the resistance value of a second resistor group 8 is weighted. Similarly to the first resistor group 7 of the first modification, a first resistor group 7 of the second modification includes four fine adjustment resistors ri (i=1, 2, 3, and 4) having resistance values different from each other and a fine adjustment resistor r5 that is always effective. Moreover, a fine adjustment switch unit 9 of the second modification is configured similarly to the fine adjustment switch unit 9 of the first modification.

The second resistor group 8 of the second modification has m coarse adjustment resistors Rj (j=1, 2, . . . , m) having resistance values different from each other. The m coarse adjustment resistors Rj are arranged between the first resistor group 7 and the second input terminal 3b and are connected in series. The coarse adjustment resistors R1, R2, . . . , and Rm are arranged in this order from the power supply VSS side toward the second input terminal 3b.

The m coarse adjustment resistors Rj (j=1, 2, . . . , m) have a resistance value Rc (j). The minimum value of the resistance values Rc (j) of the m coarse adjustment resistors Rj is R [Ω]. In FIG. 8, the coarse adjustment resistor R1 has the minimum resistance value R [Ω]. The resistance value R of the coarse adjustment resistor R1 is 16×r [Ω]. The resistance value Rc (j) of each of the coarse adjustment resistors Rj is defined as the following Equation (3).

$$Rc ( j ) = {2}^{j - 1} \times R \qquad ( 3 )$$

That is, the resistance value Rc (2) of the coarse adjustment resistor R2 is 2×R [Ω], the resistance value Rc (3) of the coarse adjustment resistor R3 is 4×R [Ω], and the resistance value Rc (m) of the coarse adjustment resistor Rm is 2^{m-1}×R [Ω].

The coarse adjustment switch unit 10 connects an arbitrary number of coarse adjustment resistors Rj to the power supply VSS and the first resistor group 7 in series. The coarse adjustment switch unit 10 of the second modification includes a plurality of switches Scj (j=1, 2, . . . , m). Closing a switch Scj results in bypassing a corresponding coarse adjustment resistor Rj. The coarse adjustment switch unit 10 can set an arbitrary number of coarse adjustment resistors Rj from zero to m out of the m coarse adjustment resistors Rj as effective resistors. That is, the coarse adjustment switch unit 10 can form 2^{m} types of combined resistances from 0 [Ω] to (2^{m}−1)×R by combining m coarse adjustment resistors Rj. In addition, the coarse adjustment switch unit 10 can increase or decrease the resistance value Rs of the second resistor group 8 by R [Ω] from 0 [Ω] to (2^{m}−1)×R [Ω].

The voltage detection circuit 6 of the second modification can detect the voltage of the power supply VSS by a procedure substantially similar to that of the voltage detection circuit 6 of the above embodiment. A detection procedure of the voltage detection circuit 6 of the second modification will be described with reference to the flowchart of FIG. 3.

In Step S10, the control unit 50 sets the resistance value Rs of the second resistor group 8 to 0 [Ω], and in Step S20, sets the resistance value rs of the first resistor group 7 to the maximum value. In this case, the control unit 50 sets all the fine adjustment resistors ri of the first resistor group 7 as effective resistors. Therefore, the resistance value rs of the first resistor group 7 is 16×r [Ω], which is the maximum value.

In Step S30, the control unit 50 determines whether or not a detection signal is acquired from the comparator 3. If positive determination is made in Step S30 and the process proceeds to Step S40, the control unit 50 determines whether or not the resistance value Rs of the second resistor group 8 is (2^{m}−1)×R [Ω], which is the maximum value. If negative determination is made in Step S40 and the process proceeds to Step S50, the control unit 50 increases the resistance value Rs of the second resistor group 8 by R [Ω].

That is, the control unit 50 increases the resistance value Rs of the second resistor group 8 by an increment of R [Ω] until the output of the comparator 3 becomes a non-detection signal. When the non-detection signal is received from the comparator 3, the process proceeds to the second sequence of fine adjustment.

In Step S60, the control unit 50 closes all the switches Sfi of the fine adjustment switch unit 9 and sets the resistance value rs of the first resistor group 7 to r [Ω]. If positive determination is made in Step S70 that the output of the comparator 3 is a detection signal, the process proceeds to Step S80.

In Step S80, the control unit 50 determines whether or not the resistance value rs of the first resistor group 7 is 16×r [Ω], which is the maximum value. If negative determination is made in Step S80 and the process proceeds to Step S90, the control unit 50 increases the resistance value rs of the first resistor group 7 by r [Ω]. If positive determination is made in Step S80, the voltage detection ends.

The voltage detection circuit 6 according to the second modification of the embodiment can change the resistance value Rs of the second resistor group 8 in 2^{m} steps by m (2≤m) coarse adjustment resistors Rj. As a result, the voltage detection range can be widened. Furthermore, the voltage detection circuit 6 has n (2≤n) weighted fine adjustment resistors ri and thus can change the resistance value rs of the first resistor group 7 in 2ⁿ stages. Therefore, the voltage detection circuit 6 of the second modification can expand the detection range and improve the resolution while suppressing the number of resistors.

As described above, the voltage detection circuit 6 according to the second modification includes m coarse adjustment resistors Rj having resistance values different from each other. The number m is a natural number greater than or equal to 2. The minimum value of the resistance values of the m coarse adjustment resistors Rj is R [Ω]. The resistance value Rc (j) of each of the m coarse adjustment resistors Rj is 2^{j-1}×R. The voltage detection circuit 6 according to the second modification can expand the voltage detection range while suppressing an increase in the number of coarse adjustment switches Scj.

Note that, in the first resistor group 7, the fine adjustment resistor r5 may be omitted. In this case, the minimum value of the resistance value of the coarse adjustment resistors Rj is given by R=15×r [Ω].

### Third Modification of Embodiment

A third modification of the embodiment will be described. In the above embodiment, in the second sequence of fine adjustment, the voltage detection is terminated in a case where the output of the comparator 3 is switched. Alternatively, the voltage detection may be terminated at a moment when it is estimated that the output of the comparator 3 will be switched.

A voltage detection method according to the third modification will be described with reference to FIG. 4. In the second sequence of fine adjustment illustrated on the right side of FIG. 4, the output of the comparator 3 becomes a non-detection signal at a time point when the resistance value rs of the first resistor group 7 increases to 3×r [Ω] (step3), and the voltage detection ends. In this example, a case where a detection voltage V13 in a case where the resistance value rs is 3×r [Ω] does not reach the threshold Vth will be examined. In this case, if the resistance value rs of the first resistor group 7 is set to 4×r [Ω], which is the maximum value, it is estimated that the output of the comparator 3 is switched to a non-detection signal.

In the third modification, in a case where the output of the comparator 3 remains as the detection signal even when the resistance value rs increases up to 3×r [Ω], the voltage detection is terminated. This determination is based on the result of the first sequence of coarse adjustment. In the first sequence, detection by the comparator 3 is switched to the non-detection signal when the total resistance value reaches 5×R [Ω]. Therefore, it can be estimated that the detection by the comparator 3 is switched to a non-detection signal when the total resistance value reaches 5×R [Ω] even in the second sequence of fine adjustment. As described above, in a case where the output of the comparator 3 is not switched when the resistance value rs of the first resistor group 7 is smaller by one than the maximum value, the voltage detection may be terminated. The detected voltage value of the power supply VSS in this case is adopted in a case where it is presumed that the output of the comparator 3 is switched with the resistance value rs of the first resistor group 7 set as the maximum value.

The content disclosed in the above embodiments and modifications can be executed in combination as appropriate.

### REFERENCE SIGNS LIST

1 ELECTRONIC WATCH
2 EXTERIOR CASE
3 COMPARATOR
3a FIRST INPUT TERMINAL
3b SECOND INPUT TERMINAL
4 BATTERY
5 WINDSHIELD
6 VOLTAGE DETECTION CIRCUIT
7 FIRST RESISTOR GROUP
8 SECOND RESISTOR GROUP
9 FINE ADJUSTMENT SWITCH UNIT
10 COARSE ADJUSTMENT SWITCH UNIT
21 BODY
22 LUG
31 DIAL PLATE
32 SECOND HAND
33 MINUTE HAND
34 HOUR HAND
50 CONTROL UNIT
ri FINE ADJUSTMENT RESISTOR
Rj COARSE ADJUSTMENT RESISTOR
Sfi, Scj SWITCH
VDD GROUND POTENTIAL
VSS POWER SUPPLY
Vref REFERENCE VOLTAGE
VR VARIABLE RESISTOR

1. A voltage detection circuit comprising:
a comparator having a first input terminal to which a reference voltage is input, and a second input terminal;
a plurality of fine adjustment resistors arranged between a detection target and the second input terminal;
at least one coarse adjustment resistor disposed between the detection target and the second input terminal;
a fine adjustment switch unit that connects an arbitrary number of the fine adjustment resistors to the detection target and the coarse adjustment resistor in series;
a coarse adjustment switch unit that connects an arbitrary number of the coarse adjustment resistors to the detection target and the fine adjustment resistors in series; and
a control unit that controls an opening and closing operation of a switch included in the fine adjustment switch unit and an opening and closing operation of a switch included in the coarse adjustment switch unit, wherein
the coarse adjustment resistor includes a resistor having a resistance value equal to a total value obtained by adding up resistance values of the plurality of fine adjustment resistors.

2. The voltage detection circuit according to claim 1, wherein
the plurality of fine adjustment resistors include n pieces of the fine adjustment resistors having resistance values different from each other,
the n is a natural number greater than or equal to 2,
a minimum value of the resistance values of the n fine adjustment resistors is r, and
a resistance value rf (i) (i=1, 2, . . . , n) of each of the n fine adjustment resistors is 2ⁱ⁻¹×r.

3. The voltage detection circuit according to claim 1, wherein
the at least one coarse adjustment resistor includes m pieces of the coarse adjustment resistors having resistance values different from each other,
the m is a natural number greater than or equal to 2,
a minimum value of resistance values of the m coarse adjustment resistors is R, and
a resistance value Rc (j) (j=1, 2, . . . , m) of each of the m coarse adjustment resistors is 2^{j-1}×R.

4. The voltage detection circuit according to claim 1, further comprising:
a variable resistor that changes a resistance value between the second input terminal of the comparator and a ground potential, wherein
a voltage divided by the variable resistor, the fine adjustment resistors, and the coarse adjustment resistor is input to the second input terminal.

5. The voltage detection circuit according to claim 1, wherein
the control unit executes a first sequence that is a coarse adjustment detection sequence and a second sequence that is a fine adjustment detection sequence,
the first sequence is a sequence in which the number of the coarse adjustment resistors connected in series to the detection target and the fine adjustment resistor is changed until output of the comparator is switched,
the second sequence is a sequence in which the number of the fine adjustment resistors connected in series to the detection target and the coarse adjustment resistor is changed in a range of resistance values before and after the output of the comparator is switched in the first sequence,
in a case where the number of the coarse adjustment resistors connected in series in the first sequence is increased, the control unit increases the number of the fine adjustment resistors connected in series in the second sequence, and
in a case where the number of the coarse adjustment resistors connected in series in the first sequence is decreased, the control unit decreases the number of the fine adjustment resistors connected in series in the second sequence.

6. The voltage detection circuit according to claim 1, wherein
the fine adjustment switch unit is disposed on a side of the detection target with respect to the coarse adjustment resistor.

7. A watch comprising:
a voltage detection circuit according to claim 1; and
a battery as the detection target.
